(19) United States
(12) Patent Application Publication
(10) Pub. No.: US 2008/0230880 A1
(43) Pub. Date: Sep. 25, 2008

(54) Leadframe Array with Riveted Heat Sinks

(76) Inventors: Kazuaki Ano, Oita (JP); Vincent Feng, Shindian (TW)

Correspondence Address: TEXAS INSTRUMENTS INCORPORATED, P O BOX 655474, M/S 3999, DALLAS, TX, 75265, US

(21) Appl. No.: 12/013,738

(22) Filed: Jan. 14, 2008

Related U.S. Application Data
(60) Provisional application No. 60/896,141, filed on Mar. 21, 2007.

(51) Int. Cl. H01L 23/495; H01L 21/56

(52) U.S. Cl. 257/675; 438/112; 257/E23.051; 257/E21.502

(57) ABSTRACT

The invention provides improved rivet and heat sink arrangements in leadframes and IC packages. The invention discloses a semiconductor device leadframe array with numerous leadframes having integrated circuit sites provided for receiving individual integrated circuit chips. Support strips are arranged adjacent to and supporting the integrated circuit sites in an array of one or more rows. Package areas provided each include one or integrated circuit site for ultimate encapsulation in an integrated circuit package. Rivet points are located on the support strips outside of the package areas. An array of heat sinks having corresponding rivet points is riveted to the leadframe array to complete the assembly. Alternative embodiments of the invention provide apparatus and methods for the assembly of an integrated circuit package with a leadframe having an operably coupled integrated circuit chip. One or more support strips supporting the leadframe include rivet points adjacent to the integrated circuit mounting site. A heat sink is secured in coplanar contact with the leadframe using rivets secured in the rivet points of the leadframe and corresponding rivet points in the heat sink. Individual package assemblies made using the invention provide heat sinks secured in contact with the leadframe, integrated circuit, or both, without the necessity for the inclusion of glues, thermal compounds, welds, tapes, or rivets within the package assembly.

### PRIORITY ENTITLEMENT

This application is entitled to priority based on Provisional Patent Application Ser. No. 60/896,141 filed on Mar. 21, 2007, which is incorporated herein for all purposes by this reference. This application and the Provisional Patent Application have at least one common inventor and are assigned to the same entity.

### TECHNICAL FIELD

The invention relates to electronic semiconductor devices and manufacturing. More particularly, the invention relates to microelectronic integrated circuit (IC) package assemblies and heat dissipation structures for IC packages and leadframes, and to methods for their manufacture.

### BACKGROUND OF THE INVENTION

Generally speaking, semiconductor devices such as integrated circuits (ICs) are manufactured by forming layered metallic circuit components and patterns on a semiconductor wafer. Numerous such ICs are formed on a single wafer. The individual ICs are separated from one another by a singulation process, such as sawing. Each IC is typically mounted on a metallic leadframe, and the IC-leadframe assembly is then encapsulated within a package. Package material, or “encapsulant” is commonly made from viscous or semi-viscous plastic or epoxy resin, which is cured to form a hardened protective cover to shield the IC assembly from environmental hazards such as dust, heat, moisture, mechanical shock, and external electricity.

Heat is generated during the operation of packaged ICs. Due to the continuous development of microelectronic circuit technology, ICs are being made smaller, denser, and capable of operating faster than previously. Therefore, the trend in the art is that the amount of heat generated increases as the heat-dissipating area diminishes. If the rate of heat dissipation is insufficient, the excess heat may be detrimental or even destructive to the IC. As a result, a common and direct approach for increasing heat dissipation from IC packages is to use a heat sink to dissipate heat produced by IC operations. A typical approach is to fasten a heat sink in direct contact with either the leadframe or the IC.

There are several techniques known in the arts for attaching the heat sink so that it makes contact with the IC chip, leadframe, or all or portions of each. Thermally conductive glue or other compounds, also called “heat sink jelly”, “heat sink compound”, “thermal goo”, “silicon compound”, or “thermal grease” are sometimes applied directly to a heat sink placed in contact with an IC or leadframe surface. A significant disadvantage of thermal compound is that it is quite messy to handle, sometimes contaminating nearby surfaces and tools, and therefore often not suitable for mass production processes. Thermal compounds can also tend to be highly electrically conductive as well thermally conductive. Thus, there is an additional hazard that any thermal compound that drips onto the board or adjacent electrical connections during assembly can cause a catastrophic failure. Similarly, the heat sink may be welded to the leadframe, forming a fused metal join to fuse the two together. This technique has problems similar to those encountered with using flowable compounds, e.g., it is relatively messy and expensive. Another approach sometimes used to overcome some of these problems is the use of double-sided adhesive tape between the heat sink and the surface to which it is applied, e.g., leadframe and/or IC chip. This approach necessitates precise handling of the materials involved, and results in relatively slow throughput and high expense.

Therefore, it is common in the arts to use rivets for fastening heat sinks to leadframes and in order to provide a package with a heat sink while avoiding the use of thermal compounds, welding, and double-sided tape. Referring to the representative example of a package 1 shown in FIGS. 1A and 1B (prior art), a rivet joint 2 is formed inside the IC package 1 by the drilling or punching of corresponding holes in the leadframe 3 and heat sink 4, and fastening the corresponding parts with a rivet 5 through the aligned holes. Due to the location of the rivets inside the package occupying a portion of the leadframe, the pin count of a given IC package tends to be lower. Also, due to the delicate nature of the interior of the leadframe, the manufacturing process is complex and the cost is high. Not only is the leadframe susceptible to damage, resulting in yield loss, the assembly procedure is relatively slow. Rivets are nevertheless often used in the leadframe inside conventional packages where the avoidance of the use of other attachment means is desired.

Due to these and other technological challenges, improved IC packages, leadframes, heat sinks, and manufacturing methods would be useful and advantageous in the arts. The present invention is directed to overcoming, or at least reducing the effects of one or more of the problems encountered in the prior art.

### SUMMARY OF THE INVENTION

In carrying out the principles of the present invention, in accordance with preferred embodiments, the invention provides advances in the arts with novel methods and apparatus directed to providing improved heat sink arrangements on leadframes and within IC packages.

According to one aspect of the invention, a preferred embodiment of a semiconductor device leadframe array assembly includes a metal sheet having numerous leadframes with integrated circuit sites provided for receiving individual integrated circuit chips. Support strips are arranged adjacent to and supporting the integrated circuit sites in an array of one or more rows. A number of package areas each include at least one integrated circuit site for ultimate encapsulation in an integrated circuit package. Rivet points are located on the support strips outside of the package areas. An array of heat sinks having corresponding rivet points is riveted to the metal sheet.

According to another aspect of the invention, an integrated circuit package includes a leadframe having an integrated circuit site with an operably coupled integrated circuit chip. The leadframe also includes one or more support strips with numerous rivet points adjacent to the integrated circuit site. A heat sink is secured in coplanar contact with at least part of the leadframe, using rivets secured at the rivet points of the leadframe and corresponding rivet points of the heat sink.

According to another aspect of the invention, an integrated circuit package includes a leadframe having an integrated circuit site with an operably coupled integrated circuit chip. The leadframe also includes one or more support strips with numerous rivet points adjacent to the integrated circuit site. A heat sink is secured in coplanar contact with at least part of the leadframe using rivets secured at the rivet points of the leadframe and corresponding rivet points of the heat sink with at least a portion of the heat sink in coplanar contact with the integrated circuit chip.

According to yet another aspect of the invention, a method for assembling an integrated circuit chip package includes steps for providing numerous metal leadframes arranged in an array. Package areas provided on the leadframes each have one or more integrated circuit site. In further steps, an integrated circuit chip is operably coupled to each of the integrated circuit sites. The leadframe array is also provided with support strips adjacent to and supporting the leadframes in one or more rows. Rivet points are provided on the support strips. In additional steps, a heat sink array is riveted to the leadframe array using rivet points corresponding to the leadframe array rivet points. Each package area of the leadframe is subsequently encapsulated and singulated to form individual integrated circuit chip packages.

According to another aspect of the invention, an integrated circuit package assembly in a preferred embodiment includes a metal leadframe with an integrated circuit chip operably coupled to the leadframe. A heat sink is secured in coplanar contact with at least a portion of the leadframe by encapsulant encapsulating the integrated circuit chip, at least a portion of the leadframe, and at least a portion of the heat sink, such that no glue, thermal compound, weld, tape, or rivets are included within the package.

The invention has advantages including but not limited to one or more of; increased pin count, reduced manufacturing complexity, higher manufacturing yield, and reduced cost. These and other sometimes unexpectedly advantageous features and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1A (prior art) is a top view of an example of an IC package having a heat sink riveted to a leadframe according to the conventional state of the art;

FIG. 1B (prior art) is a detailed top view of a portion of the example of the IC package having a heat sink riveted to a leadframe according to the prior art as introduced in FIG. 1A;

FIG. 2 is a top perspective exploded view of an array of leadframes and a corresponding array of heat sinks illustrating an example of a preferred embodiment of the invention;

FIGS. 3A through 3F provide a cutaway partial side view of an example of the formation of a rivet in a heat sink and leadframe assembly according to a preferred embodiment of the invention;

FIG. 4 is a side view of a leadframe array according to the example of a preferred embodiment of the invention according to FIG. 2;

FIG. 5 is a top view of an example of an array of integrated circuit package assemblies having leadframes and riveted heat sinks according to a preferred embodiment of the invention;

FIG. 6A is a cut-away side view of a leadframe array, heat sinks, and packages prior to singulation according to a preferred embodiment of the invention; and

FIG. 6B is a detailed cut-away side view of a portion of the preferred embodiment of the invention shown in FIG. 6A.

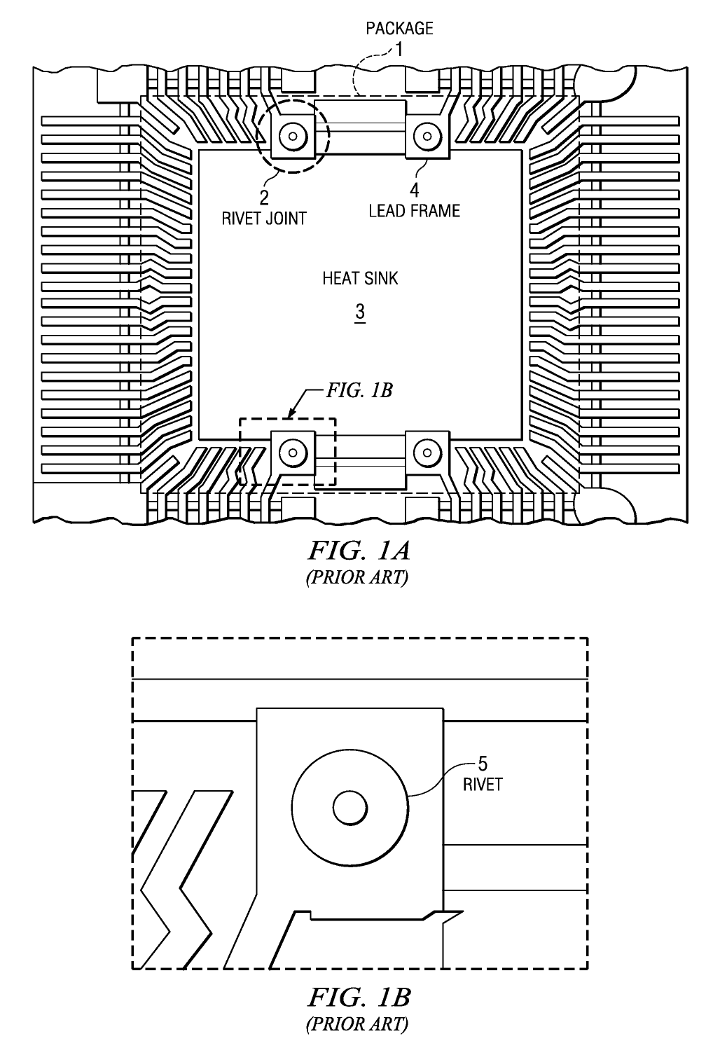

References in the detailed description correspond to like references in the various drawings unless otherwise noted. Descriptive and directional terms used in the written description such as first, second, top, bottom, upper, side, et cetera, refer to the drawings themselves as laid out on the paper and not to physical limitations of the invention unless specifically noted. The drawings are not to scale, and some features of embodiments shown and discussed are simplified or amplified for illustrating principles and features, as well as anticipated and unanticipated advantages of the invention.

### DESCRIPTION OF PREFERRED EMBODIMENTS

While the making and using of various exemplary embodiments of the present invention are discussed herein, it should be appreciated that the present invention provides inventive concepts which can be embodied in a wide variety of specific contexts. It should be understood that the invention may be practiced with semiconductor device packages of various types, configurations, and materials without altering the principles of the invention. For purposes of clarity, detailed descriptions of functions and systems familiar to those skilled in the semiconductor manufacturing equipment and processing arts are not included. In general, the invention provides apparatus and methods for attaching heat sinks and leadframes for use in semiconductor device packages.

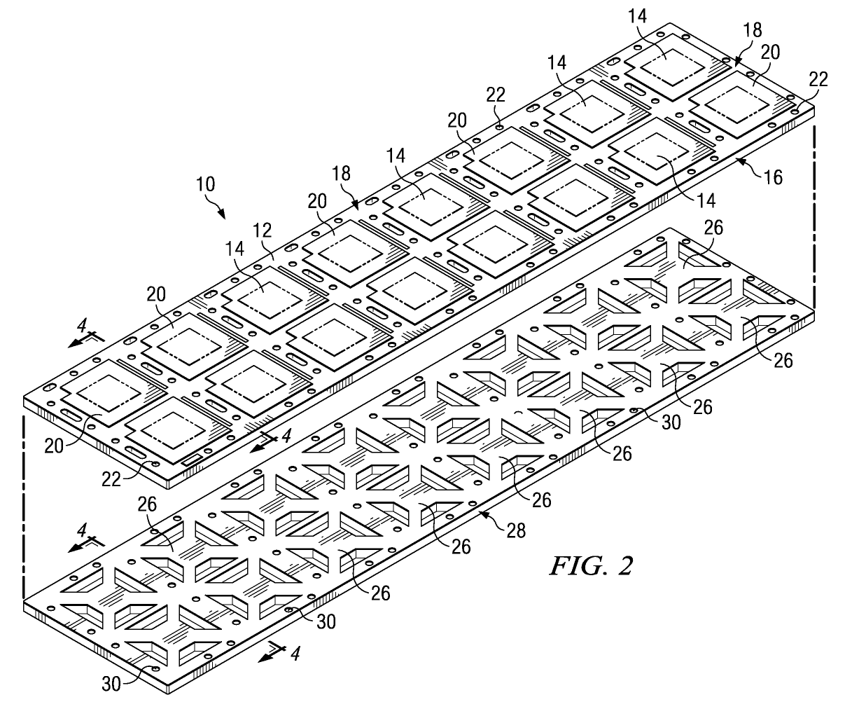

Referring initially to FIG. 2, a leadframe array assembly 10 according to a preferred embodiment of the invention is shown in an exploded top perspective view. As shown, a metal sheet 16 preferably has numerous individual metal leadframes 12, each leadframe 12 includes at least one integrated circuit site 14 in a configuration for receiving individual integrated circuit chips (ICs) familiar to practitioners of the applicable arts. The leadframes 12 may include lead fingers as known in the arts. The leadframes 12 are supported by adjacent support strips 18, preferably circumscribing the leadframes 12 arrayed in one or more rows. As indicated at reference numeral 20 of FIG. 2, package areas are provided for ultimately encapsulating a mounted IC within an IC package. Accordingly, each of the package areas 20 contains an integrated circuit mounting site 14. Rivet points 22 are provided on the support strips 18. The rivet points 22 are preferably apertures drilled, etched, or punched into the support strips 18 for receiving rivets. The rivet points 22 are suitably arranged for the attachment of heat sinks 26, arranged in a heat sink array 28, to the leadframe sheet 16 of the leadframe array assembly 10. The number and exact arrangement of the rivet points 22 are not crucial to the practice of the invention as long as the rivet points 22 are each located outside of the package areas 20, preferably on the support strips 18. The heat sink array 28 has rivet points 30 similar to those of the leadframe sheet 16. The rivet points 22 of the leadframe sheet 16 and heat sinks 26 are arranged so that they correspond in such a way that rivets may be formed in order to fasten the leadframes 12 and heat sinks 26 together in coplanar alignment.

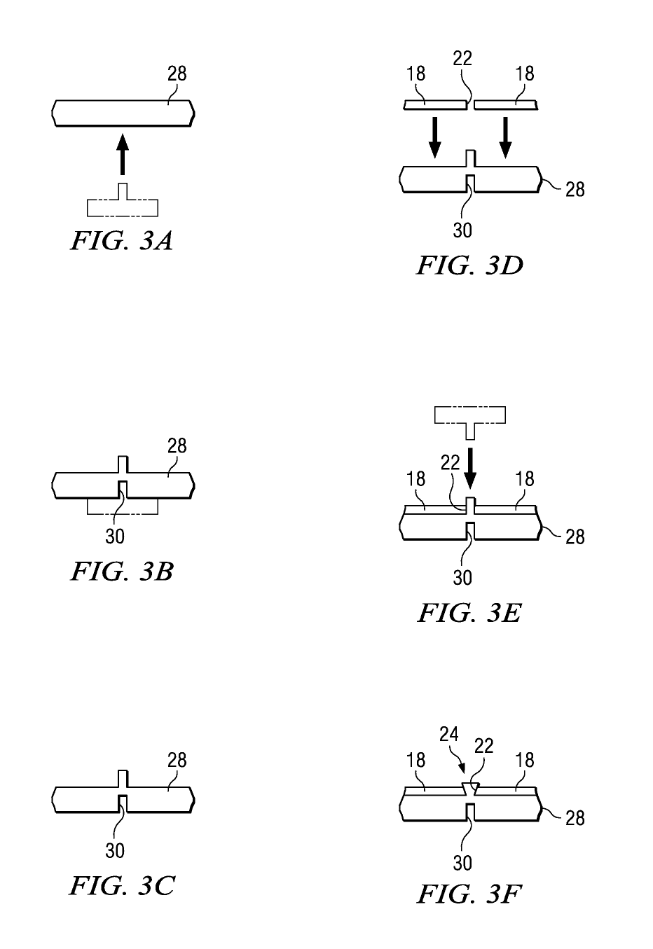

An example of the formation of a rivet 24 in the implementation of a preferred embodiment of the invention is shown in the series of figures, FIG. 3A through FIG. 3F. Many variations of the invention are possible, but the sequence shown in FIGS. 3A through 3F provide an example of the steps that may be used for forming rivets in practicing the invention, forming the embodiment as depicted in FIG. 2, for example. As shown in FIGS. 3A through 3C, the heat sink array 28 is preferably punched with a punching tool (not part of the invention) in order to form the rivet point 30 in the appropriate location. As shown in FIG. 3D, a portion of the metal sheet upon which the leadframe array is fabricated, preferably the support strip 18, includes a rivet point 22 that may be brought into alignment with the heat sink rivet point 30. After the leadframe 12 and heat sink 28 are brought into coplanar contact, as shown in FIG. 3E, a riveting tool (not part of the invention) is brought to bear on the heat sink rivet point 30, pressing the metal into the form of a rivet 24 as shown in FIG. 3F, securing the leadframe array to the heat sink array.

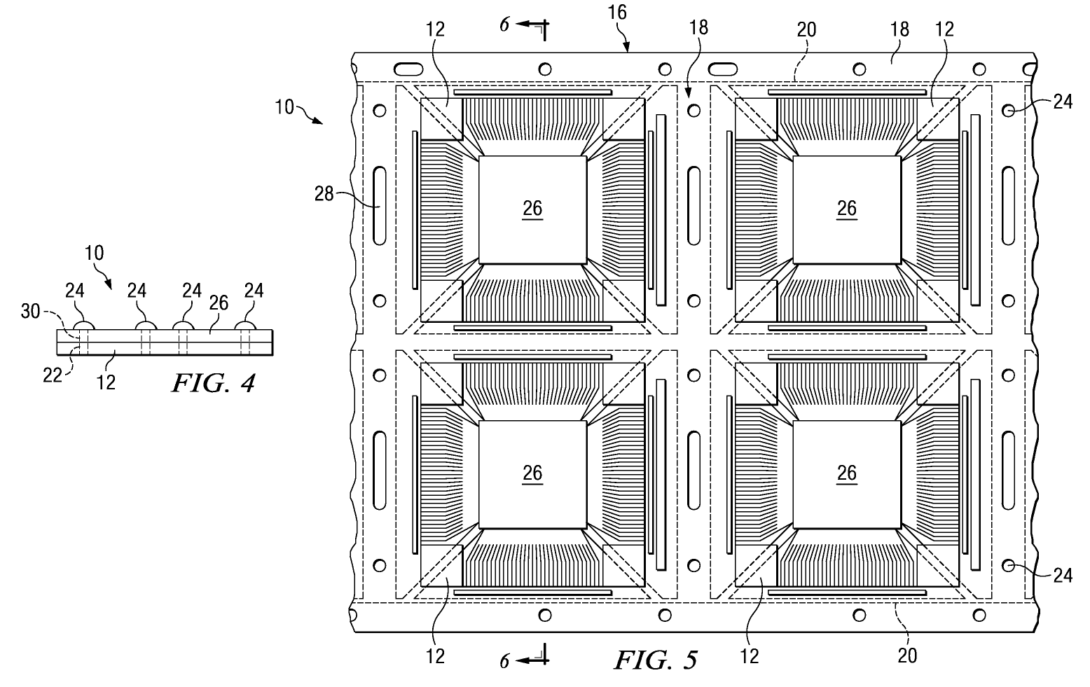

An alternative view of an exemplary embodiment of a leadframe array assembly 10 is depicted in the side view of FIG. 4. Each of the rivets 24 pass through corresponding rivet points 22 of leadframe 14 and the rivet points 30 of the heat sink array 28 where they are secured as familiar in the arts. An additional top view of a leadframe array assembly 10 of leadframes 12 and heat sinks 26 is shown in FIG. 5. The leadframe sheet 16 has an array 28 of connected heat sinks 26 shown affixed to the leadframe sheet 16 by rivets 24 installed in aligned rivet points 22, 30 spaced about the support strip 18 of the leadframe sheet 16 and the corresponding support strips 32 of the heat sink array 28. The rivets 24 are located outside of the circuit sites 14, and preferably outside of the package areas 20 provided for eventual encapsulation in a completed package. Many variations of the invention are possible. The heat sinks 26 may be placed in coplanar contact with integrated circuit chips mounted on the leadframes, for example. The invention may also be used in packages having stacked chips, spacers, and other components.

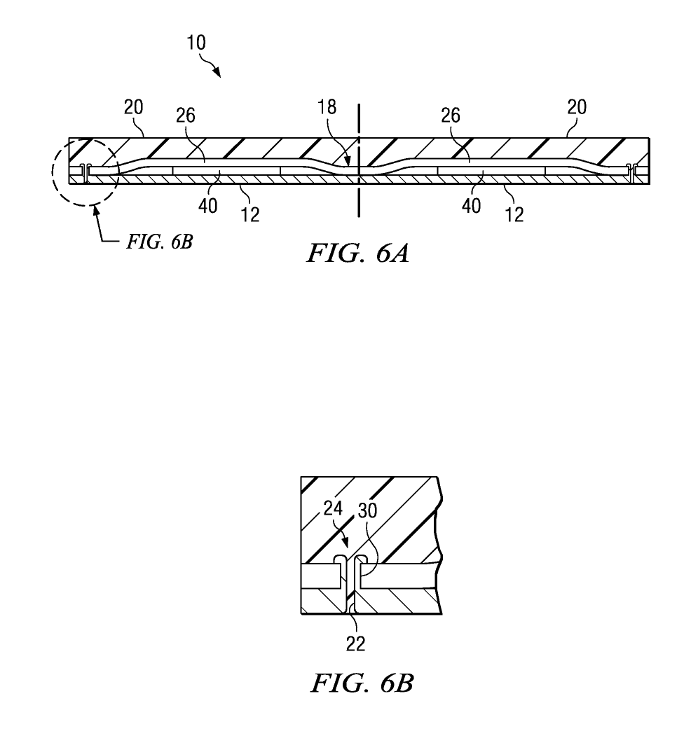

In FIGS. 6A and 6B, an example of packages 20 according to preferred embodiments of the invention are shown just prior to the singulation steps. The leadframes 12 include an integrated circuit chip 40 mounted on the chip site 14. The heat sinks 26 are secured in place in a coplanar relationship with the ICs 40 and leadframes 14 with rivets 24 installed in the adjacent rivet points 22, 30, (FIG. 5B) of the leadframe array 10 and heat sink array 28. Encapsulant 42 completes the package 20 structure.

In practicing the invention, in applications where it is desirable to locate the heat sinks on the bottom of the leadframes, the heat sink and leadframe arrays are preferably riveted together before attaching chips to their positions on the leadframes. In other applications, it is desirable to position the heat sink on the chip. in such cases the chips are affixed to the leadframes prior to riveting the heat sinks in place. The assembled leadframe array, heat sink array, and chips, are then encapsulated, preferably using block molding techniques. Subsequent to encapsulation, the array assemblies may be singulated as generally known in the arts to separate the individual packages. The heat sinks are secured immovably in place by the encapsulant, thus it is acceptable to singulate without regard to the rivet locations, sacrificing some or all of the rivets in some cases. Thus, integrated circuit packages may be provided without the use of rivets inside the finished package, and without the use of thermal compounds, welds, or tapes where avoidance of such materials is desired.

The methods and systems of the invention provide one or more advantages including but not limited to improved leadframe and IC package assembly methods, and improved apparatus advantageous in terms of thermal performance and cost. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A semiconductor device leadframe array assembly comprising:
a metal sheet having a plurality of leadframes, the leadframes each having at least one integrated circuit site for receiving an individual integrated circuit chip;
support strips adjacent to and supporting the integrated circuit sites in an array of one or more rows;
a plurality of package areas for encapsulation for the formation of an integrated circuit package, each package area comprising at least one integrated circuit site;
a plurality of rivet points on the support strips, the rivet points located outside of the package areas;
a heat sink array having a plurality of rivet points corresponding with rivet points of the metal sheet; wherein
the heat sink array and metal sheet are fastened together by rivets formed at a plurality of the rivet points.

2. The semiconductor device leadframe array according to claim 1 wherein the metal sheet further comprises aluminum.

3. The semiconductor device leadframe array according to claim 1 wherein the metal sheet further comprises copper.

4. The semiconductor device leadframe array according to claim 1 wherein the heat sink array further comprises copper.

5. An integrated circuit package comprising:
a metal leadframe;
an integrated circuit chip operably coupled to an integrated circuit site of the leadframe;
wherein the leadframe further comprises one or more support strip adjacent to the integrated circuit site, the support strip having a plurality of rivet points;
a heat sink in coplanar contact with at least a portion of the leadframe, the heat sink having rivet points corresponding with the rivet points of the leadframe; and
rivets secured at the rivet points and joining the heat sink with the leadframe.

6. The integrated circuit package according to claim 5 further comprising dielectric encapsulant material encapsulating the integrated circuit chip.

7. The integrated circuit package according to claim 5 further comprising dielectric encapsulant material encapsulating at least one surface of the package area of the leadframe.

8. The integrated circuit package according to claim 5 further comprising dielectric encapsulant material encapsulating at least a portion of a support strip.

9. The integrated circuit package according to claim 5 further comprising dielectric encapsulant material encapsulating one or more rivet.

10. The integrated circuit package according to claim 5 wherein at least a portion of the heat sink is in coplanar contact with the integrated circuit chip.

11. A method for assembling an integrated circuit chip package comprising the steps of:
providing a metal leadframe array having a plurality of leadframes, the leadframes each having a plurality of package areas, each package area comprising at least one integrated circuit site; also
providing the leadframe array with support strips adjacent to and supporting the package areas in an array of one or more rows;
providing a plurality of rivet points on the support strips, the rivet points located outside of the package areas;
operably coupling an integrated circuit chip to each of the integrated circuit sites;
placing a heat sink array in coplanar contact with the leadframe array support strips, the heat sink array having a plurality heat sinks corresponding with the package areas of the leadframe array, the heat sink array also having one or more support strips also comprising rivet points corresponding with rivet points of the leadframe support strips;
fastening the heat sink array and leadframe array together using rivets formed in a plurality of the corresponding rivet points;
subsequently encapsulating each package area comprising at least one leadframe integrated circuit site, at least one integrated circuit chip, and one heat sink; and
thereafter singulating individual integrated circuit chip packages by cutting between the package areas.

12. The method for assembling an integrated circuit chip package according to claim 11 wherein at least a portion of the heat sink is placed and fastened in coplanar contact with the integrated circuit chip.

13. The method for assembling an integrated circuit chip package according to claim 11 wherein the singulating steps further comprise sawing through one or more of the support strips.

14. An integrated circuit package assembly comprising:
a metal leadframe;
an integrated circuit chip operably coupled to the leadframe;
a heat sink secured in coplanar contact with at least a portion of the leadframe; wherein,
the heat sink is secured by encapsulant encapsulating the integrated circuit chip, at least a portion of the leadframe, and at least a portion of the heat sink.

15. The integrated circuit package assembly according to claim 14 wherein at least a portion of the heat sink is secured in coplanar contact with the integrated circuit chip.
